(19) United States
(12) Patent Application Publication
(10) Pub. No.: US 2024/0373621 A1
(43) Pub. Date: Nov. 7, 2024

(54) METHOD FOR MANUFACTURING A SEMICONDUCTOR DEVICE

(71) Applicant: Samsung Electronics Co., Ltd., Suwon-si (KR)

(72) Inventors: Seungmin SHIN, Suwon-si (KR); Kijong PARK, Suwon-si (KR); Sangjun PARK, Suwon-si (KR); Younggeun SONG, Suwon-si (KR); Ilyoung YOON, Suwon-si (KR); Yongjin LEE, Suwon-si (KR)

(73) Assignee: Samsung Electronics Co., Ltd., Suwon-si (KR)

(21) Appl. No.: 18/627,685

(22) Filed: Apr. 5, 2024

(30) Foreign Application Priority Data
May 3, 2023 (KR) 10-2023-0057685

(51) Int. Cl. H10B 12/00

(52) U.S. Cl. CPC H10B 12/05; H10B 12/315

(57) ABSTRACT

In a method for manufacturing a semiconductor device, comprising; forming mold insulation patterns on a substrate, forming an oxide semiconductor layer conformally on sidewalls and upper surfaces of the mold insulation patterns and the substrate, forming a first metal oxide layer on the oxide semiconductor layer, patterning the first sacrificial layer, the first metal oxide layer, and the oxide semiconductor layer to form a first structure including a preliminary first metal oxide layer pattern, a preliminary oxide semiconductor layer pattern and a first sacrificial layer pattern stacked, forming a preliminary second metal oxide layer pattern selectively on a sidewall of the preliminary oxide semiconductor layer pattern, removing selective portions of the first structure and the preliminary second metal oxide layer pattern to form an oxide semiconductor layer pattern, a first metal oxide layer pattern, and a second metal oxide layer pattern.

### CROSS-REFERENCE TO RELATED APPLICATION

This application claims priority under 35 USC § 119 to Korean Patent Application No. 10-2023-0057685, filed on May 3, 2023, in the Korean Intellectual Property Office (KIPO), the contents of which are incorporated by reference herein in their entirety.

### BACKGROUND

Various example embodiments relate to a method of manufacturing a semiconductor device. Particularly, various example embodiments relate to a method of manufacturing a semiconductor device having a vertical channel transistor including an oxide semiconductor layer pattern.

For high integration of a semiconductor device, a vertical channel transistor including a vertical channel disposed in perpendicular to a substrate of a surface may be used in the semiconductor device. A channel layer of the vertical channel transistor may include an oxide semiconductor layer pattern.

### SUMMARY

Various example embodiments provide a method of manufacturing a semiconductor device including a vertical channel transistor.

According to some example embodiments, there is provided a method for manufacturing a semiconductor device, comprising; forming mold insulation patterns on a substrate, each of the mold insulation patterns extending in a second direction parallel to an upper surface of the substrate, forming an oxide semiconductor layer conformally on sidewalls and upper surfaces of the mold insulation patterns and the substrate between the mold insulation patterns, forming a first metal oxide layer on the oxide semiconductor layer to cover the oxide semiconductor layer, forming a first sacrificial layer on the first metal oxide layer to fill a trench between the mold insulation patterns, patterning the first sacrificial layer, the first metal oxide layer, and the oxide semiconductor layer to form a first structure extending a first direction, parallel to the upper surface of the substrate and perpendicular to the second direction, the first structure including a preliminary first metal oxide layer pattern, a preliminary oxide semiconductor layer pattern and a first sacrificial layer pattern stacked, forming a preliminary second metal oxide layer pattern selectively on a sidewall of the preliminary oxide semiconductor layer pattern, removing selective portions of the first structure and the preliminary second metal oxide layer pattern from the upper surfaces of the mold insulation patterns to form an oxide semiconductor layer pattern, a first metal oxide layer pattern, and a second metal oxide layer pattern covering a surface of the oxide semiconductor layer pattern on the sidewalls of the mold insulation patterns and on the substrate between the mold insulation patterns, removing the remaining first sacrificial layer pattern, and forming a conductive layer pattern extending in the second direction on the sidewalls of the mold insulation patterns, and on the first and second metal oxide layer patterns formed on the sidewalls of the mold insulation patterns.

According to some example embodiments, there is provided a method for manufacturing a semiconductor device, comprising; forming first conductive layer patterns on a substrate, each of the first conductive layer patterns extending in a first direction parallel to an upper surface of the substrate, forming mold insulation patterns on the first conductive layer pattern, each of the mold insulation patterns extending in a second direction parallel to the upper surface of the substrate and perpendicular to the first direction, forming an oxide semiconductor layer conformally on sidewalls and upper surfaces of the mold insulation patterns and an upper surface of the first conductive layer pattern between the mold insulation patterns, forming a first metal oxide layer on the oxide semiconductor layer to cover the oxide semiconductor layer, forming a first sacrificial layer on the first metal oxide layer to fill a trench between the mold insulation patterns, patterning the first sacrificial layer, the first metal oxide layer and the oxide semiconductor layer to form a first structure extending the first direction, the first structure including a preliminary first metal oxide layer pattern, a preliminary oxide semiconductor layer pattern and a first sacrificial layer pattern stacked, forming a preliminary second metal oxide layer pattern selectively on a sidewall of the preliminary oxide semiconductor layer pattern, forming a second sacrificial layer on the substrate to cover the first structure and the preliminary second metal oxide layer pattern, planarizing upper portions of the first structure, the second sacrificial layer and the preliminary second metal oxide layer pattern to expose the upper surface of the mold insulation pattern to form an oxide semiconductor layer pattern having a U-shaped cross-section, a first metal oxide layer pattern, a second metal oxide layer pattern covering surfaces of the oxide semiconductor layer pattern, and a sacrificial layer structure on the first and second metal oxide layer patterns, removing the sacrificial layer structure, and forming a second conductive layer pattern extending in the second direction on the sidewalls of the mold insulation patterns and on the first and second metal oxide layer patterns formed on the sidewalls of the mold insulation patterns.

According to some example embodiments, there is provided a method for manufacturing a semiconductor device, comprising; forming a preliminary oxide semiconductor layer pattern on a substrate, forming a preliminary metal oxide layer pattern selectively on an exposed surface of the preliminary oxide semiconductor layer pattern, the preliminary metal oxide layer pattern covering the exposed surface of the preliminary oxide semiconductor layer pattern, forming a sacrificial layer on the preliminary metal oxide layer pattern, removing at least portions of the sacrificial layer, the preliminary metal oxide layer pattern and the preliminary oxide semiconductor layer pattern to form an oxide semiconductor layer pattern, a metal oxide layer pattern, and a sacrificial layer pattern, removing the remaining sacrificial layer pattern, and forming a conductive layer pattern on the metal oxide layer pattern.

In various example embodiments, a metal oxide layer pattern may be formed on the surface of the oxide semiconductor layer pattern. Thus, during a manufacturing process of a semiconductor device, the oxide semiconductor layer pattern may be protected by the metal oxide layer pattern. Therefore, defects due to damage or removal of the oxide semiconductor layer pattern may be decreased. In addition, the metal oxide layer pattern may be provided as a gate insulation layer of the vertical channel transistor, so that the vertical channel transistor may be manufactured by simple processes.

### BRIEF DESCRIPTION OF THE DRAWINGS

Various example embodiments will be more clearly understood from the following detailed description taken in conjunction with the accompanying drawings. FIGS. 1 to 31 represent various non-limiting, example embodiments as described herein.

FIG. 1 is a cross-sectional view of a semiconductor device in accordance with various example embodiments;

FIG. 2 is a perspective view illustrating a portion of a semiconductor device in accordance with various example embodiments;

FIGS. 3 and 4 are perspective views illustrating a portion of a semiconductor device in accordance with various example embodiments;

FIGS. 5 to 23 are perspective views and cross-sectional views illustrating a method of manufacturing a semiconductor device in accordance with various example embodiments; and

FIGS. 24 to 31 are perspective views and cross-sectional views illustrating a method of manufacturing a semiconductor device in accordance with various example embodiments.

### DETAILED DESCRIPTION

Reference will now be made in detail to embodiments, examples of which are illustrated in the accompanying drawings, wherein like reference numerals refer to like elements throughout. In this regard, some example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to in other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

When the terms “about” or “substantially” are used in this specification in connection with a numerical value, it is intended that the associated numerical value includes a manufacturing or operational tolerance (e.g., +10%) around the stated numerical value.

Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Hereinafter, various example embodiments will be described in detail with reference to the accompanying drawings.

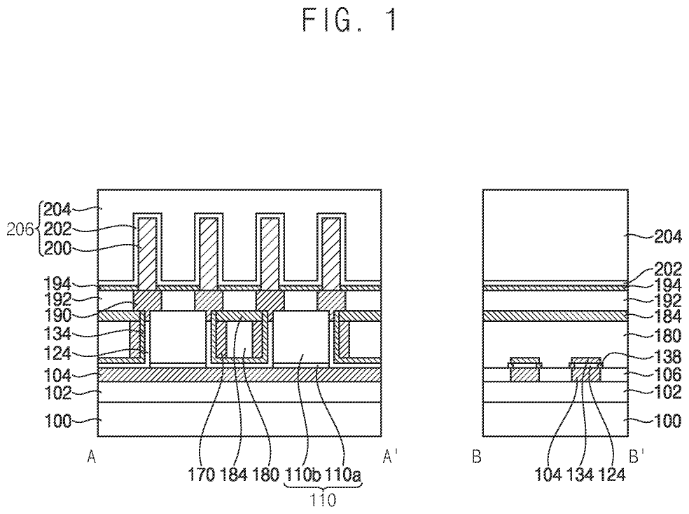

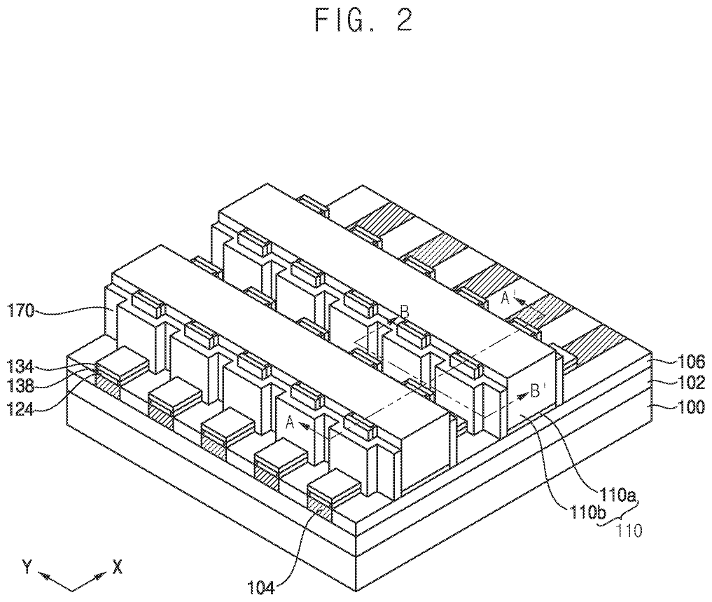

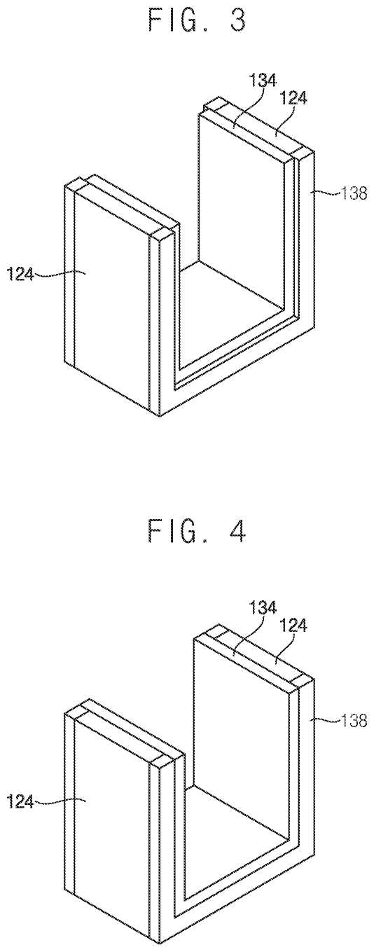

FIG. 1 is a cross-sectional view of a semiconductor device in accordance with various example embodiments. FIG. 2 is a perspective view illustrating a portion of a semiconductor device in accordance with various example embodiments. FIGS. 3 and 4 are perspective views illustrating a portion of a semiconductor device in accordance with various example embodiments.

The semiconductor device may be a DRAM device. FIG. 1 includes cross-sectional views of portions A-A′ and B-B′ of FIG. 2. In FIG. 2, illustration of some elements (e.g., a third conductive layer pattern and a capacitor) is omitted to avoid complexity of the drawing. FIGS. 3 and 4 show only the oxide semiconductor layer pattern and the first and second metal oxide layer patterns.

Referring to FIGS. 1 and 2, the semiconductor device may be formed on a substrate 100. The semiconductor device may include a first conductive layer pattern 104, a mold insulation pattern 110, an oxide semiconductor layer pattern 124, and a first metal oxide layer pattern 134, the second metal oxide layer pattern 138, a second conductive layer pattern 170, a third conductive layer pattern 190 and a capacitor 206. The semiconductor device may further include a first lower insulation layer 102, a second lower insulation layer 106, a first insulation layer pattern 180, a second insulation layer pattern 192, a capping layer pattern 184, and an etch stop layer 194. The semiconductor device may include a vertical channel transistor (VCT) formed on the oxide semiconductor layer pattern 124.

The first lower insulation layer 102 may be formed on the substrate 100. The first lower insulation layer 102 may include, e.g., silicon oxide. The upper surface of the first lower insulation layer 102 may be substantially flat. The first lower insulation layer 102 may cover an upper surface of the substrate 100.

The first conductive layer pattern 104 may be disposed on the first lower insulation layer 102, and may have a line shape extending in a first direction X parallel to the upper surface of the substrate 100. A plurality of first conductive layer patterns 104 may be spaced apart from each other in a second direction Y parallel to the upper surface of the substrate 100 and perpendicular to the first direction X. The first conductive layer patterns 104 may be parallel to each other.

The second lower insulation layer 106 may fill a space between the first conductive layer patterns 104. The upper surfaces of the first conductive layer patterns 104 and the second lower insulation layer 106 may be coplanar with each other, and may be substantially flat. Accordingly, the upper surface of the first conductive layer pattern 104 may be exposed between the second lower insulation layers 106. The first conductive layer pattern 104 may serve as a bit line.

Although not shown, an insulation layer including silicon nitride may be further formed on the first lower insulation layer 102.

In some example embodiments, the first conductive layer pattern 104 may include doped polysilicon, metal, conductive metal nitride, conductive metal silicide, conductive metal oxide, or a combination thereof. For example, the first conductive layer pattern 104 may include doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or a combination thereof, but example embodiments may not be limited thereto. The first conductive layer pattern 104 may include a single layer or multiple layers of the above materials.

The mold insulation pattern 110 having a line shape extending in the second direction Y may be disposed on the first conductive layer pattern 104 and the second lower insulation layer 106. The mold insulation pattern 110 may be disposed to cross the first conductive layer pattern 104.

The mold insulation pattern 110 may include one insulation pattern or two or more insulation patterns stacked. In some example embodiments, the mold insulation pattern 110 may have a structure in which a silicon nitride layer pattern 110a and a silicon oxide layer pattern 110b are stacked. In this case, the silicon oxide layer pattern 110b may serve as most of a mold structure, and the silicon nitride layer pattern 110a may serve as an etch stop layer. Therefore, the thickness of the silicon nitride layer pattern 110a may be less than a thickness of the silicon oxide layer pattern 110b.

The oxide semiconductor layer pattern 124 may be conformally formed along profiles of a sidewall of the mold insulation pattern 110 and the upper surface of the first conductive layer pattern 104 between the mold insulation patterns 110. The oxide semiconductor layer pattern 124 may have a U-shape, in a cross-section view taken along the first direction.

The bottom of the oxide semiconductor layer pattern 124 may contact the upper surface of the first conductive layer pattern 104. In FIG. 2, the oxide semiconductor layer pattern 124 may have a width in the second direction Y slightly less than a width in the second direction Y of the first conductive layer pattern 104, but may not be limited thereto. For example, the width of the oxide semiconductor layer pattern 124 in the second direction Y may be equal to or greater than the width of the first conductive layer pattern 104 in the second direction Y.

The oxide semiconductor layer patterns 124 may be spaced apart from each other in the second direction Y. The mold insulation pattern 110 may be disposed between the oxide semiconductor layer patterns 124 in the first direction X, and the oxide semiconductor layer patterns 124 may be aligned in the first direction X.

In some example embodiments, the oxide semiconductor layer pattern 124 may be a material of an amorphous state. A material of the oxide semiconductor layer pattern 124 may include ZnO. In some example embodiments, the oxide semiconductor layer pattern 124 may include InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof, however example embodiments are not limited thereto. For example, the oxide semiconductor layer pattern 124 may include InxGayZnzO (IZGO).

The first metal oxide layer pattern 134 and the second metal oxide layer pattern 138 may be formed only on a surface of the oxide semiconductor layer pattern 124. The first and second metal oxide layer patterns 134 and 138 may not be formed other than the surface of the oxide semiconductor layer pattern 124. For example, the first and second metal oxide layer patterns 134 and 138 may not substantially cover the upper surface of the second lower insulation layer 106.

The first metal oxide layer pattern 134 may be formed on the sidewall of the mold insulation pattern 110 and an upper surface of the oxide semiconductor layer pattern 124 overlapping the upper surface of the first conductive layer pattern 104 between the mold insulation patterns 110. In some example embodiments, in a cross-sectional view taken along the first direction, the first metal oxide layer pattern 134 may have a U-shape.

The second metal oxide layer pattern 138 may be formed on a sidewall of the oxide semiconductor layer pattern 124 in the second direction Y.

The first and second metal oxide layer patterns 134 and 138 may surround the upper surface and sidewalls of the oxide semiconductor layer pattern 124. The surface of the oxide semiconductor layer pattern 124 may be protected by the first and second metal oxide layer patterns 134 and 138. The first and second metal oxide layer patterns 134 and 138 may be formed by different steps of processes.

In some example embodiments, as shown in FIG. 3, the second metal oxide layer pattern 138 may protrude laterally from the first metal oxide layer pattern 134. Accordingly, a boundary between the first and second metal oxide layer patterns 134 and 138 may be distinguished.

In some example embodiments, as shown in FIG. 4, the second metal oxide layer pattern 138 may not protrude from the sidewall of the first metal oxide layer pattern 134.

The first and second metal oxide layer patterns 134 and 138 may be a dielectric material having a permittivity higher than a permittivity of silicon nitride.

In some example embodiments, the first metal oxide layer pattern 134 and the second metal oxide layer pattern 138 may include substantially the same material. In some example embodiments, the first and second metal oxide layer patterns 134 and 138 may include, e.g., aluminum oxide, zirconium oxide, hafnium oxide, or titanium oxide.

In some example embodiments, a structure including the oxide semiconductor layer pattern 124 and the first and second metal oxide layer patterns 134 and 138 may cover the upper surface of the first conductive layer pattern 104.

The second conductive layer pattern 170 may be formed on the sidewall of the mold insulation pattern 110 and on portions of the first and second metal oxide layer patterns 134 and 138 in areas formed on the sidewall of the mold insulation pattern 110. The second conductive layer pattern 170 may extend in the second direction Y. Two separated second conductive layer patterns 170 may be disposed on sides of each of the oxide semiconductor layer patterns 124 having a U-shape, respectively.

In some example embodiments, an uppermost surface of the second conductive layer pattern 170 may be lower than an uppermost surface of the first metal oxide layer pattern 134.

The first and second metal oxide layer patterns 134 and 138 may serve as a gate insulation layer of a vertical channel transistor, and the second conductive layer pattern 170 may serve as a gate electrode of the vertical channel transistor. Also, the second conductive layer pattern 170 may extend in the second direction Y so that the second conductive layer pattern 170 may serve as a word line in the semiconductor device.

One oxide semiconductor layer pattern 124 may serve as an active pattern, and two vertical channel transistors connected in series may be disposed on each of the oxide semiconductor layer pattern 124 serving as the active pattern.

The second conductive layer pattern 170 may include doped polysilicon, metal, conductive metal nitride, conductive metal silicide, conductive metal oxide, or a combination thereof. For example, the plurality of second conductive layer patterns 170 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but example embodiments may not be limited thereto.

The first insulation layer pattern 180 may be formed on the second conductive layer pattern 170, the second lower insulation layer 106, the first metal oxide layer pattern 134, the second metal oxide layer pattern 138 and the mold insulation pattern 110. The first insulation layer pattern 180 may fill a space between the mold insulation patterns 110. An upper surface of the first insulation layer pattern 180 may be coplanar with the uppermost surface of the second conductive layer pattern 170, or may be lower than the uppermost surface of the second conductive layer pattern 170.

The capping layer pattern 184 may be formed on the upper surface of the first insulation layer pattern 180 and the uppermost surface of the second conductive layer pattern 170. In some example embodiments, an upper surface of the capping layer pattern 184 may be coplanar with an upper surface of the mold insulation pattern 110.

In some example embodiments, the first insulation layer pattern 180 may include silicon oxide. The capping layer pattern 184 may include silicon nitride.

The third conductive layer pattern 190 may contact an end of the oxide semiconductor layer pattern 124. That is, the third conductive layer pattern 190 may contact the uppermost surface of the oxide semiconductor layer pattern 124.

The third conductive layer pattern 190 may include a first portion extending in the vertical direction from the same level as the upper surface of the capping layer pattern 184 to the uppermost surface of the oxide semiconductor layer pattern 124, and a second portion connected to the first portion and disposed on the upper surface of the capping layer pattern 184 and the mold insulation pattern 110. The third conductive layer pattern 190 may serve as a pad conductive pattern (i.e., a landing pad) connected to the capacitor 206.

The third conductive layer pattern 190 may include doped polysilicon, metal, conductive metal nitride, conductive metal silicide, conductive metal oxide, or a combination thereof. For example, the third conductive layer pattern 190 may include doped polysilicon, Al, Cu, Ti, Ta, Ru, W, Mo, Pt, Ni, Co, TiN, TaN, WN, NbN, TiAl, It may be made of TiAlN, TiSi, TiSiN, TaSi, TaSiN, RuTiN, NiSi, CoSi, IrOx, RuOx, or a combination thereof, but example embodiments are not limited thereto.

The second insulation layer pattern 192 may be disposed between the third conductive layer patterns 190. The upper surfaces of the third conductive layer patterns 190 and the second insulation layer pattern 192 may be coplanar with each other. The second insulation layer pattern 192 may include silicon oxide.

The etch stop layer 194 may be disposed on the second insulation layer pattern 192 and the third conductive layer pattern 190. The etch stop layer 194 may include silicon nitride, silicon oxynitride, or silicon carbide, but example embodiments are not limited thereto.

The capacitor 206 may pass through the etch stop layer 194, and may contact the upper surface of the third conductive layer pattern 190.

The capacitor 206 may include a lower electrode 200, a dielectric layer 202, and an upper electrode 204 sequentially stacked. The lower electrode 200 may directly contact the upper surface of the third conductive layer pattern 190. The lower electrode 200 may have a pillar shape or a cylinder shape, but example embodiments are not limited thereto.

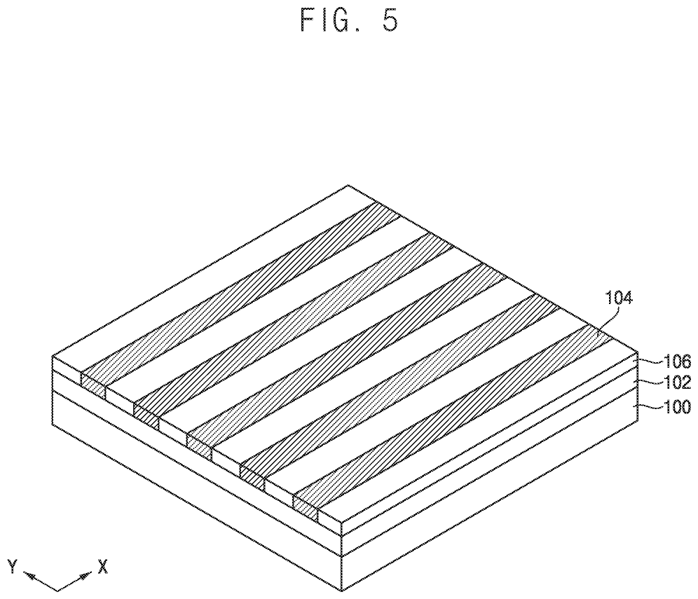

FIGS. 5 to 23 are perspective views and cross-sectional views illustrating a method of manufacturing a semiconductor device in accordance with various example embodiments.

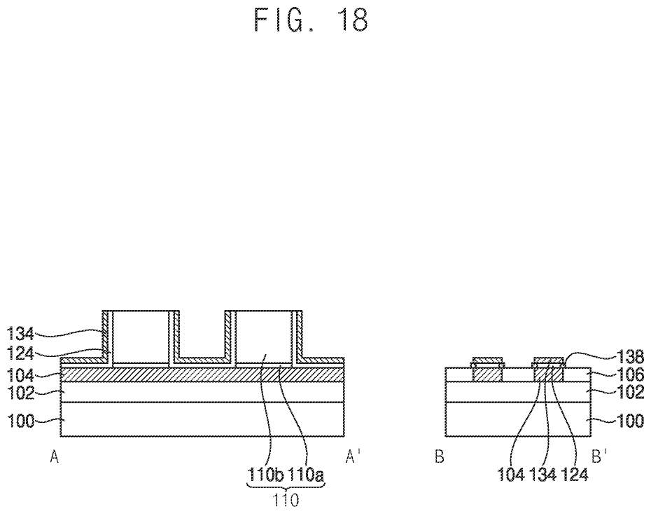

FIGS. 5 to 10, 12, 15 to 17 and 19 are perspective views, and FIGS. 18 and 20 to 23 are cross-sectional views. FIGS. 11, 13 and 14 are enlarged perspective views of a portion of a semiconductor device. Each of the cross-sectional views includes cross-sectional views taken along a line of A-A′ and a line of B-B′ of FIG. 17.

Referring to FIG. 5, a first lower insulation layer 102 may be formed on a substrate 100.

A first conductive layer pattern 104 having a line shape extending in the first direction X may be formed on the first lower insulation layer 102. A plurality of first conductive layer patterns 104 may be spaced apart from each other in the second direction Y, and the first conductive layer patterns 104 may be parallel to each other. A second lower insulation layer 106 may be formed between the first conductive layer patterns 104. The upper surfaces of the first conductive layer patterns 104 and the second lower insulation layer 106 may be coplanar with each other, and may be substantially flat.

Although not shown, an insulation layer including silicon nitride may be further formed on the first lower insulation layer 102.

In some example embodiments, the first conductive layer patterns 104 may be formed in an embossed manner. In this case, a first conductive layer may be formed on the first lower insulation layer 102, and the first conductive layer may be patterned by a photolithography process to form the first conductive layer patterns 104. Thereafter, an insulation layer may be formed on the first conductive layer patterns 104, and the insulation layer may be planarized until the upper surfaces of the first conductive layer patterns 104 may be exposed to form the second lower insulation layer 106.

In some example embodiments, the first conductive layer patterns 104 may be formed by a damascene process. In this case, a second lower insulation layer 106 may be formed on the first lower insulation layer 102, and the second lower insulation layer 106 may be patterned by a photolithography process to form trenches. A first conductive layer may be formed on the second the second lower insulation layer 106 to fill the trenches, and the first conductive layer may be planarized until the upper surface of the second lower insulation layer 106 may be exposed to form the first conductive layer patterns 104 in the trenches, respectively.

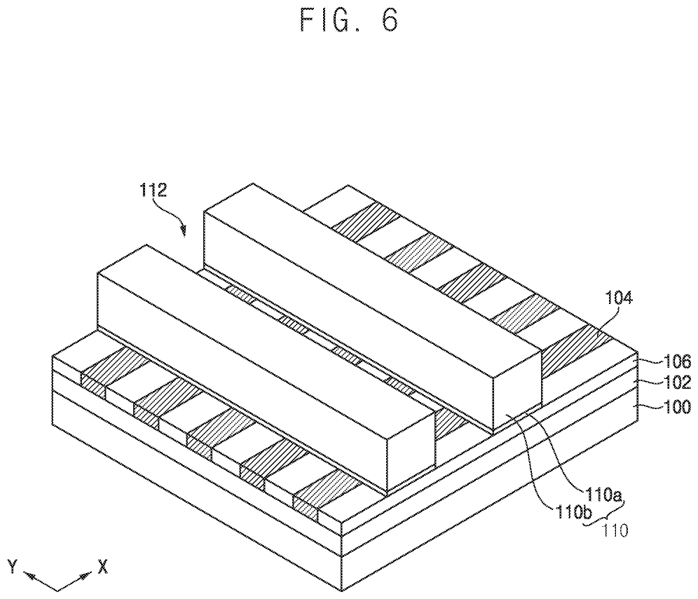

Referring to FIG. 6, a mold insulation layer may be formed on the first conductive layer pattern 104 and the second lower insulation layer 106, and the mold insulation layer may be patterned to form mold insulation patterns 110. Each of the mold insulation patterns 110 may be formed as one insulation pattern or two or more insulation patterns stacked.

In some example embodiments, a silicon nitride layer and a silicon oxide layer may be formed on the first conductive layer pattern 104 and the second lower insulation layer 106, and the silicon nitride layer and the silicon oxide layer may be patterned to form the mold insulation patterns 110. Accordingly, each of the mold insulation patterns 110 may have a structure in which a silicon nitride layer pattern 110a and a silicon oxide layer pattern 110b are stacked.

The mold insulation pattern 110 may have a line shape extending in the second direction Y. The mold insulation patterns 110 may be spaced apart from each other in the first direction X. A first trench 112 extending in the second direction Y may be formed between the mold insulation patterns 110. The first conductive layer pattern 104 and the second lower insulation layer 106 may be exposed by the bottom of the first trench 112.

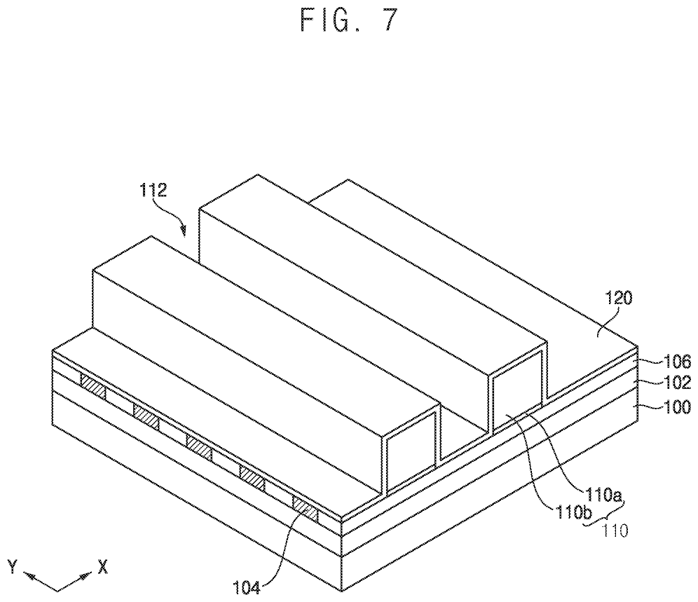

Referring to FIG. 7, an oxide semiconductor layer 120 may be conformally formed on surfaces of the mold insulation patterns 110 and the bottom of the first trench 112. The oxide semiconductor layer 120 may serve as an active pattern by subsequent processes.

The oxide semiconductor layer 120 may cover the surfaces of the mold insulation patterns 110, the upper surface of the first conductive layer pattern 104 and the upper surface of the second lower insulation layer 106. The oxide semiconductor layer 120 may be formed to have a uniform thickness from the surface of the first trench 112, so that the oxide semiconductor layer 120 may not completely fill the first trench 112.

In some example embodiments, the oxide semiconductor layer 120 may be in an amorphous state.

The material of the oxide semiconductor layer 120 may include ZnO. In some example embodiments, the oxide semiconductor layer 120 may include InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof, but example embodiments are not limited thereto. For example, the oxide semiconductor layer 120 may include InxGayZnzO.

In some example embodiments, the oxide semiconductor layer 120 may be formed by atomic layer deposition process, a plasma enhanced chemical vapor deposition process, or a low-pressure chemical vapor deposition process. However, example embodiments are not limited thereto.

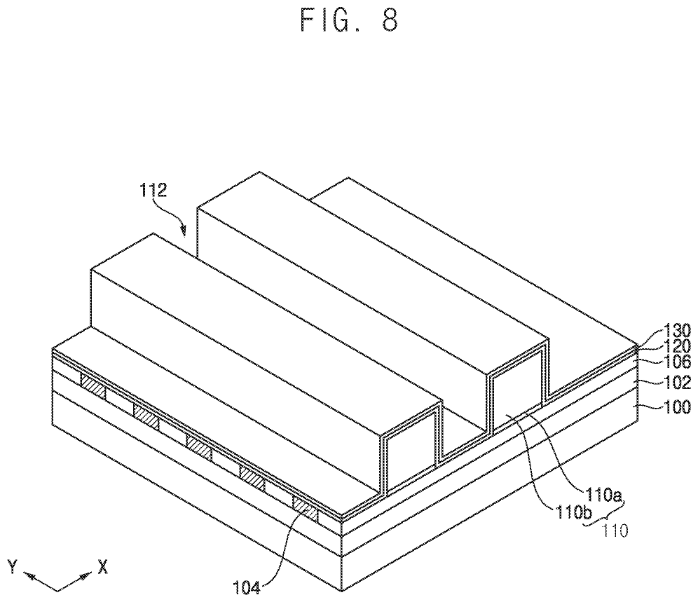

Referring to FIG. 8, a first metal oxide layer 130 may be formed on the oxide semiconductor layer 120. The first metal oxide layer 130 may be a dielectric material having a permittivity higher than a permittivity of silicon oxide. The first metal oxide layer 130 may serve as a gate insulation layer by subsequent processes. In addition, the first metal oxide layer 130 may serve as a protective layer for protecting the oxide semiconductor layer 120.

The first metal oxide layer 130 may be formed to have a uniform thickness and be formed on the surface of the oxide semiconductor layer 120. The first metal oxide layer 130 may be conformally formed on the surface of the oxide semiconductor layer 120, so that the first metal oxide layer 130 may not completely fill the first trench 112.

In some example embodiments, the first metal oxide layer 130 may include, e.g., aluminum oxide, zirconium oxide, hafnium oxide, or titanium oxide. However, example embodiments are not limited thereto.

In some example embodiments, the first metal oxide layer 130 may be formed by reacting with the surface of the oxide semiconductor layer 120. Therefore, the first metal oxide layer 130 may be selectively formed only on the surface of the oxide semiconductor layer 120. The surface of the oxide semiconductor layer 120 may be replaced with the first metal oxide layer 130 by a partial thickness, and thus the thickness of the oxide semiconductor layer 120 may finely decrease.

In some example embodiments, a metal precursor may be introduced onto the oxide semiconductor layer 120, and the metal precursor may react with an oxide included in the oxide semiconductor layer 120. The process of forming the first metal oxide layer 130, may be done without introducing an oxygen agent (e.g., water). When the first metal oxide layer 130 including aluminum oxide is formed, an aluminum precursor may react with the oxide included in the oxide semiconductor layer 120 to form the first metal oxide layer 130. The aluminum precursor may include, e.g., trimethyl aluminum (TMA), aluminum chloride, or the like, but example embodiments are not limited thereto. When the first metal oxide layer 130 including a hafnium oxide is formed, a hafnium precursor may react with the oxide in the oxide semiconductor layer 120 to form the first metal oxide layer 130. When the first metal oxide layer 130 including a titanium oxide layer is formed, a titanium precursor may react with the oxide in the oxide semiconductor layer 120 to form the first metal oxide layer 130. When the first metal oxide layer 130 including a zirconium oxide is formed, a zirconium precursor may react with the oxide in the oxide semiconductor layer 120 to form the first metal oxide layer 130.

In some example embodiments, the first metal oxide layer 130 may be formed by atomic layer deposition process. The first metal oxide layer 130 may be formed by alternately introducing the metal precursor and the oxygen agent onto the oxide semiconductor layer 120.

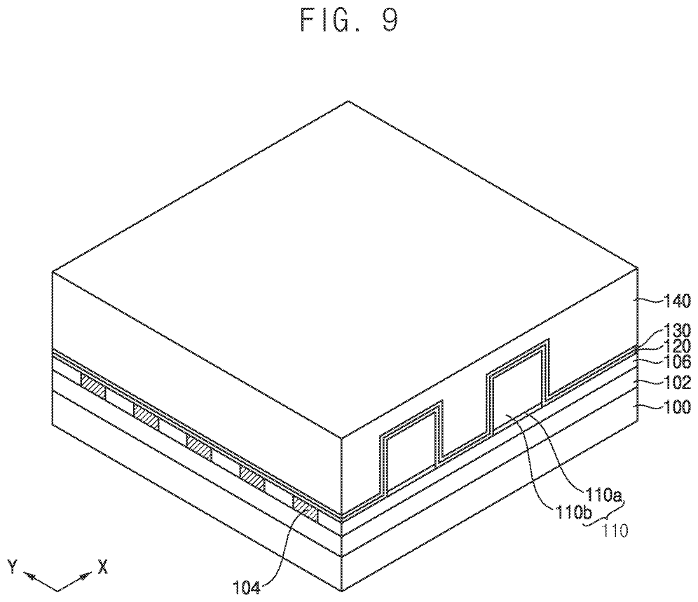

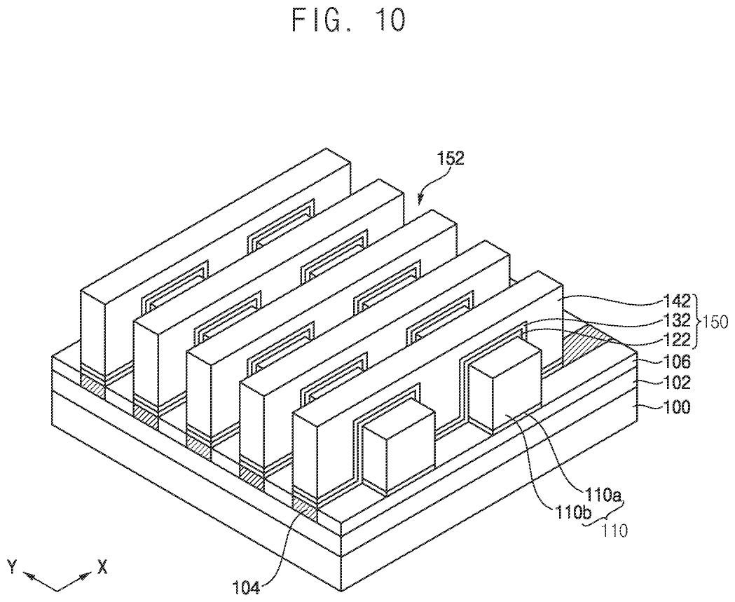

Referring to FIG. 9, a first sacrificial layer 140 may be formed on the first metal oxide layer 130. The first sacrificial layer 140 may be formed on the first metal oxide layer 130, and may fill the first trench 112. The upper surface of the first sacrificial layer 140 may be substantially flat. The first sacrificial layer 140 may be formed for easy patterning of the oxide semiconductor layer 120. Since the oxide semiconductor layer 120 is covered with the first metal oxide layer 130, the oxide semiconductor layer 120 may not directly contact the first sacrificial layer 140.

In some example embodiments, the first sacrificial layer 140 may include a spin-on hard (SOH) mask material. The spin-on hard mask material may include amorphous carbon.

Referring to FIGS. 10 and 11, an etching mask (not shown) may be formed on the first sacrificial layer 140. The first sacrificial layer 140 may be anisotropically etched using the etching mask to form a preliminary first sacrificial layer pattern 142. Subsequently, the first metal oxide layer 130 and the oxide semiconductor layer 120 may be anisotropically etched using the preliminary first sacrificial layer pattern 142 as an etching mask to form a first structure 150 including a preliminary oxide semiconductor layer pattern 122, a preliminary first metal oxide layer pattern 132, and a preliminary first sacrificial layer pattern 142 stacked. The first structure 150 may be formed on the first conductive layer pattern 104, the second lower insulation layer 106 and the mold insulation pattern 110.

The etching mask may be a photoresist pattern. The etching mask may overlap the upper surface of the first conductive layer pattern 104. Accordingly, the first structure 150 may extend in the first direction X, and may cover the upper surface of the first conductive layer pattern 104. The width of the first structure 150 in the second direction may be equal to or greater than the width of the first conductive layer pattern 104 in the second direction. A plurality of first structures 150 may be spaced apart from each other in the second direction Y. A second trench 152 may be formed between the first structures 150. The second lower insulation layer 106 and the mold insulation pattern 110 are exposed by the second trench 152.

In the first structure 150, an upper surface of the preliminary oxide semiconductor layer pattern 122 may directly contact the preliminary first metal oxide layer pattern 132. The preliminary oxide semiconductor layer pattern 122, the preliminary first metal oxide layer pattern 132 and the preliminary first sacrificial layer pattern 142 may be exposed by a sidewall of the first structure 150.

Referring to FIGS. 12 to 14, a preliminary second metal oxide layer pattern 136 may be selectively formed on the preliminary oxide semiconductor layer pattern 122 exposed by the sidewall of the first structure 150.

In some example embodiments, the preliminary first metal oxide layer pattern 132 and the preliminary second metal oxide layer pattern 136 may include substantially the same material. In this case, the preliminary first metal oxide layer pattern 132 and the preliminary second metal oxide layer pattern 136 may be treated as one metal oxide layer pattern. The upper surface and sidewall of the preliminary oxide semiconductor layer pattern 122 may be surrounded by the preliminary first metal oxide layer pattern 132 and the preliminary second metal oxide layer pattern 136. Therefore, the preliminary oxide semiconductor layer pattern 122 may not be exposed to the outside.

In some example embodiments, the preliminary second metal oxide layer pattern 136 may be formed by reacting with an exposed surface of the preliminary oxide semiconductor layer pattern 122. The sidewall of the preliminary oxide semiconductor layer pattern 122 may be replaced with the preliminary second metal oxide layer pattern 136 by a partial thickness.

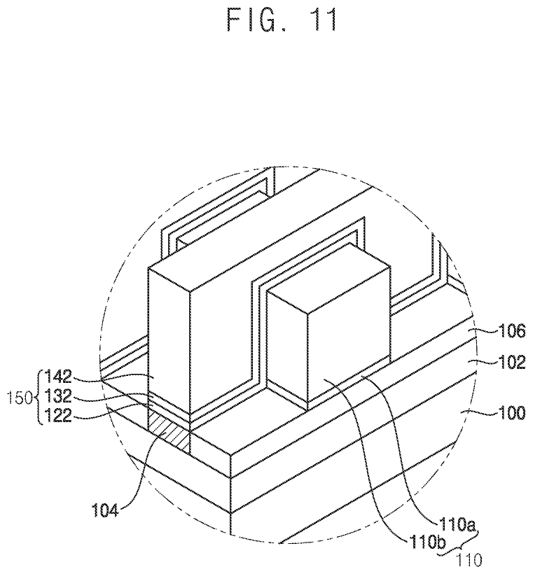

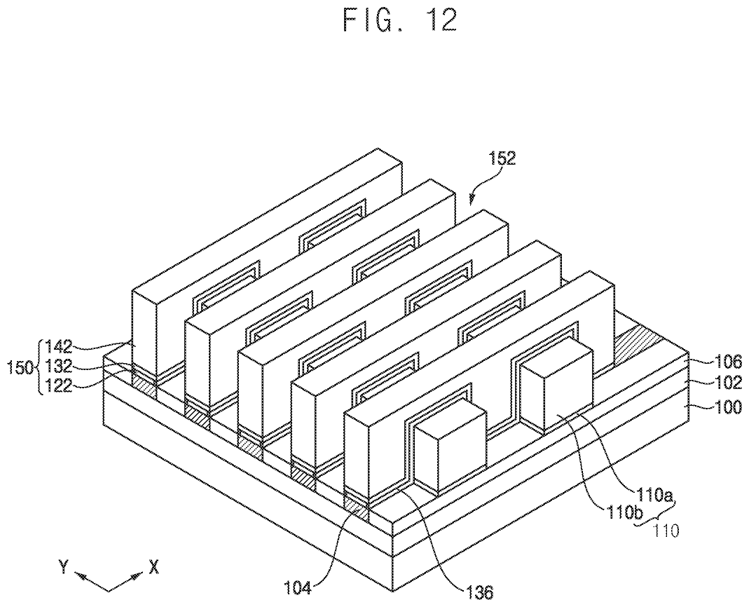

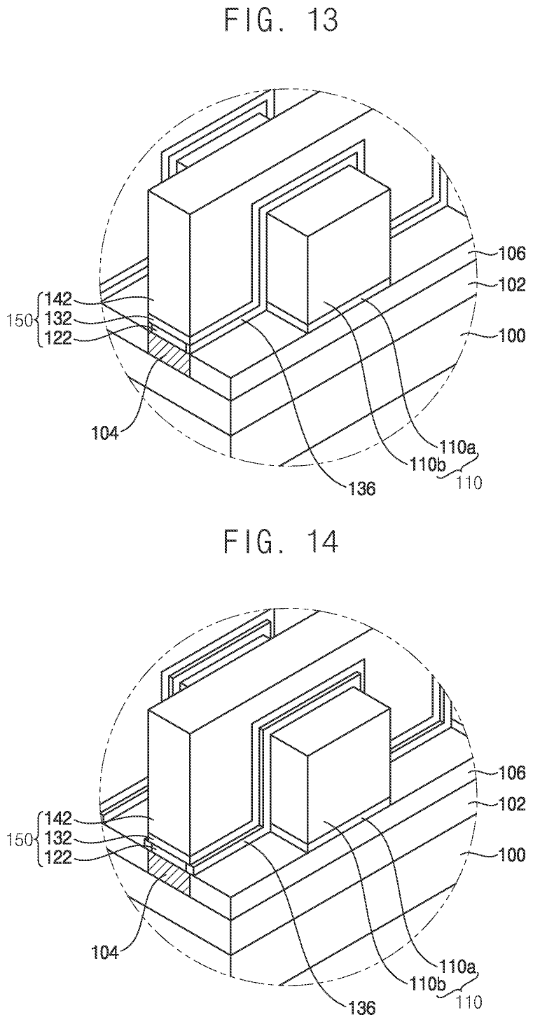

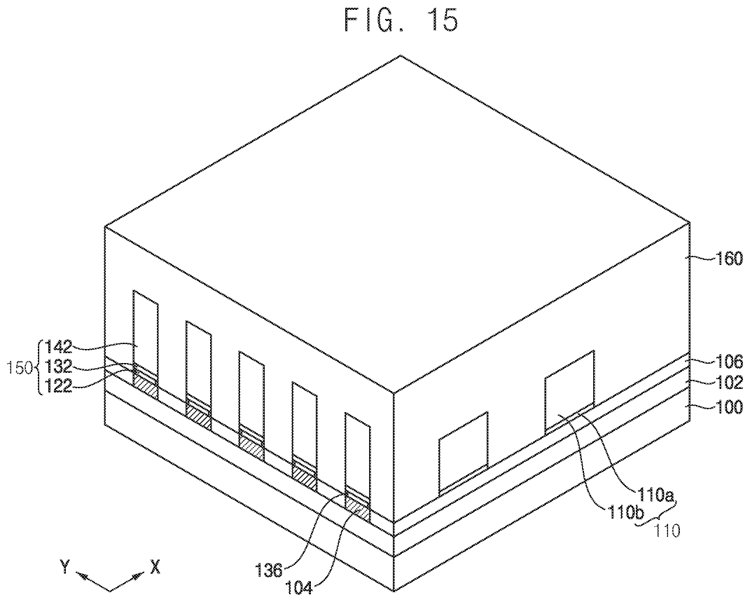

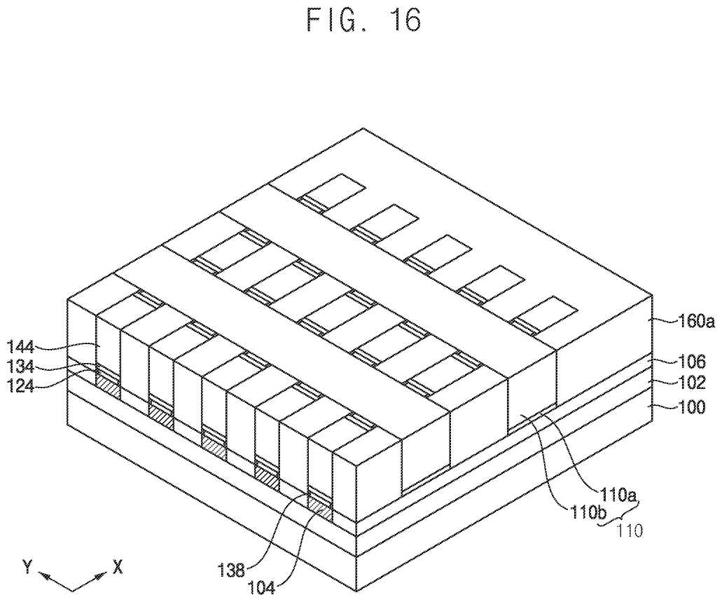

In some example embodiments, as shown in FIG. 14, according to a thickness and a surface reaction of the preliminary second metal oxide layer pattern 136, the preliminary second metal oxide layer pattern 136 may protrude laterally from the preliminary first metal oxide layer pattern 132. Accordingly, the boundary between the preliminary first metal oxide layer pattern 132 and the preliminary second metal oxide layer pattern 136 may be distinguished.

In some example embodiments, as shown in FIG. 13, the preliminary second metal oxide layer pattern 136 may not protrude laterally from the sidewall of the preliminary first metal oxide layer pattern 132. To avoid complexity in the drawings, each of perspective views shows that the preliminary second metal oxide layer pattern 136 does not protrude from the sidewall of the preliminary first metal oxide layer pattern 132.

In some example embodiments, a metal precursor may be introduced onto the first structure 150, and the metal precursor may react with an oxide included in the preliminary oxide semiconductor layer pattern 122 to form the preliminary second metal oxide layer pattern 136. The process of forming the preliminary second metal oxide layer pattern 136, may be done without introducing an oxygen agent (e.g., water).

When the preliminary second metal oxide layer pattern 136 including aluminum oxide is formed, an aluminum precursor, e.g., trimethyl aluminum (TMA), aluminum chloride, or the like may be used. However, example embodiments are not limited thereto. When the preliminary second metal oxide layer pattern 136 including a hafnium oxide layer is formed, a hafnium precursor may be used. When the preliminary second metal oxide layer pattern 136 including a titanium oxide layer is formed, a titanium precursor may be used. When the preliminary second metal oxide layer pattern 136 including a zirconium oxide layer is formed, a zirconium precursor may be used.

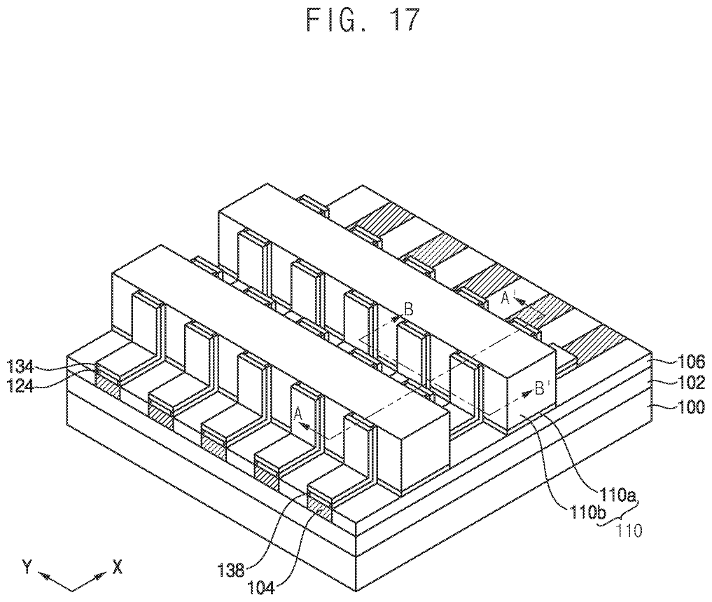

Referring to FIG. 15, a second sacrificial layer 160 may be formed on the first structures 150, the preliminary second metal oxide layer pattern 136, the second lower insulation layer 106 and the mold insulation pattern 110. The second sacrificial layer 160 may fill the second trench 152. Also, an upper surface of the second sacrificial layer 160 may be substantially flat, and the upper surface of the second sacrificial layer 160 may be higher than an upper surface of the first structure 150.

In some example embodiments, the second sacrificial layer 160 and the preliminary first sacrificial layer pattern 142 may include substantially the same material. Accordingly, the second sacrificial layer 160 and the preliminary first sacrificial layer pattern 142 may be treated as one sacrificial layer pattern.

In some example embodiments, the second sacrificial layer 160 may include a spin-on hard (SOH) mask material. The spin-on hard mask material may include amorphous carbon.

Since the upper surface and the sidewall of the preliminary oxide semiconductor layer pattern 122 are surrounded by the preliminary first metal oxide layer pattern 132 and the preliminary second metal oxide layer pattern 136, the preliminary oxide semiconductor layer pattern 122 may not directly contact the second sacrificial layer 160.

Referring to FIG. 16, upper portions of the second sacrificial layer 160, the preliminary first sacrificial layer pattern 142, the preliminary first metal oxide layer pattern 132, the preliminary second metal oxide layer pattern 136 and the preliminary oxide semiconductor layer pattern 122 may be removed by planarization process until the upper surface of the mold insulation pattern may be exposed. Thus, a second sacrificial layer pattern 160a, a first sacrificial layer pattern 144, a first metal oxide layer pattern 134, a second metal oxide layer pattern 138 and an oxide semiconductor layer pattern 124 may be formed. The first sacrificial layer pattern 144, and the second sacrificial layer pattern 160a may collectively be known as the sacrificial layer structure.

The planarization process may include an etch-back process or a chemical mechanical polishing process.

The oxide semiconductor layer pattern 124 and the first metal oxide layer pattern 134 may be formed along profiles of the sidewall of the mold insulation pattern 110 and the upper surface of the first conductive layer pattern 104 between the mold insulation patterns 110. Each of the oxide semiconductor layer pattern 124 and the first metal oxide layer pattern 134 may have a U-shape (referred to FIG. 17). The bottom of the oxide semiconductor layer pattern 124 may contact the first conductive layer pattern 104. The oxide semiconductor layer patterns 124 may be spaced apart from each other in the second direction Y. The mold insulation pattern 110 may be disposed between the oxide semiconductor layer patterns 124 in the first direction X, and the oxide semiconductor layer patterns 124 may be aligned in the first direction X.

The first metal oxide layer pattern 134 may be formed on the sidewall of the mold insulation pattern 110 and the upper surface of the oxide semiconductor layer pattern 124 overlapping the upper surface of the first conductive layer pattern 104 between the mold insulation patterns 110. The second metal oxide layer pattern 138 may be formed on the sidewall of the oxide semiconductor layer pattern 124 in the second direction Y. Therefore, the surface of the oxide semiconductor layer pattern 124 may not be exposed to the outside. Thus, the surface of the oxide semiconductor layer pattern 124 may be protected by the first and second metal oxide layer patterns 134 and 138.

Referring to FIGS. 17 and 18, the first and second sacrificial layer patterns 144 and 160a may be removed.

The removal process of the first and second sacrificial layer patterns 144 and 160a may include an ashing process. After performing the ashing process, wet cleaning using a cleaning solution (i.e., chemical) may be performed.

After performing the removal process, the second lower insulation layer 106, the first metal oxide layer pattern 134, the second metal oxide layer pattern 138 and the mold insulation pattern 110 may be exposed. The surface of the oxide semiconductor layer pattern 124 may be covered with the first metal oxide layer pattern 134 and the second metal oxide layer pattern 138, so that the oxide semiconductor layer pattern 124 may not be exposed to the outside. That is, the surface of the oxide semiconductor layer pattern 124 formed on the sidewall of the mold insulation pattern 110 and on the upper surface of the first conductive layer pattern 104 may be covered with the first and second metal oxide layer patterns 134 and 138. However, an uppermost portion of the oxide semiconductor layer pattern 124 having the same plane as the uppermost surface of the mold insulation pattern 110 may be partially exposed.

In the removal process of the first and second sacrificial layer patterns 144 and 160a, the ashing process and the cleaning process may be performed so that a layer positioned under the first and second sacrificial layer patterns 144 and 160a are not removed or damaged. In addition, after the removal process of the first and second sacrificial layer patterns 144 and 160a, residues of the first and second sacrificial layer patterns 144 and 160a may not remain on an exposed surface of the layer. The residues may cause defects (e.g., a patterning failure, a reliability failure) in subsequent processes.

If the first and second metal oxide layer patterns 134 and 138 are not formed on the oxide semiconductor layer pattern 124, the first and second sacrificial layer patterns 144 and 160a may directly contact the oxide semiconductor layer pattern 124. In this case, since the oxide semiconductor layer pattern 124 has low etching resistance in the ashing process and the wet cleaning process of the first and second sacrificial layer patterns 144 and 160a, the oxide semiconductor layer pattern 124 may be damaged or removed in the ashing process and wet cleaning process. Particularly, the ZnO included in the oxide semiconductor layer pattern 124 may have poor stability and endurance against a cleaning solution used in the wet cleaning process.

In the wet cleaning process, the cleaning solution for reducing damage of the oxide semiconductor layer pattern 124 may be limited. Only the cleaning solution having a pH within a specific range may be used. Therefore, the cleaning process may not be performed for a substantial length of time. For example, when the oxide semiconductor layer pattern 124 includes ZnO, the cleaning solution may only have a pH within the range of 8 to 10, and may only be used for a limited amount of time. In addition, since the amount of time the cleaning process may be performed for is limited, the effectiveness of the cleaning process may be decreased. Therefore, after the removal process of the first and second sacrificial layer patterns 144 and 160a, the residues of the first and second sacrificial layer patterns 144 and 160a may remain on the surface of the oxide semiconductor layer pattern 124.

In some example embodiments, the surfaces of the first and second sacrificial layer patterns 144 and 160a may not directly contact the oxide semiconductor layer pattern 124. Therefore, the oxide semiconductor layer pattern 124 may not be exposed at a portion where the first and second sacrificial layer patterns 144 and 160a are removed. The first and second metal oxide layer patterns 134 and 138 may be exposed by the portion where the first and second sacrificial layer patterns 144 and 160a are removed. The first and second metal oxide layer patterns 134 and 138 may have an etch resistance higher than an etch resistance of the oxide semiconductor layer pattern 124, during the ashing process and the wet cleaning process. Therefore, in the removal process of the first and second sacrificial layer patterns 144 and 160a, the first and second metal oxide layer patterns 134 and 138 may not be removed or damaged. Since the oxide semiconductor layer pattern 124 is protected by the first and second metal oxide layer patterns 134 and 138, damage or removal of the oxide semiconductor layer pattern 124 may be prevented or limited. In addition, since the first and second metal oxide layer patterns 134 and 138 are not removed or damaged during the wet cleaning process, the cleaning solution used in the wet cleaning process may not be limited and the cleaning process may be performed for a more substantial length of time, thusly increasing the effectiveness of the cleaning process. Therefore, after the removal process of the first and second sacrificial layer patterns 144 and 160a, the residues of the first and second sacrificial layer patterns 144 and 160a may not remain on the surfaces of the first and second metal oxide layer patterns 134 and 138.

The oxide semiconductor layer pattern 124 may serve as an active pattern in a semiconductor device. The oxide semiconductor layer pattern 124 between the mold insulation patterns 110 may contact the upper surface of the first conductive layer pattern 104. The first and second metal oxide layer patterns 134 and 138 formed on the upper surface of the oxide semiconductor layer pattern 124 may serve as a gate insulation layer of a vertical channel transistor.

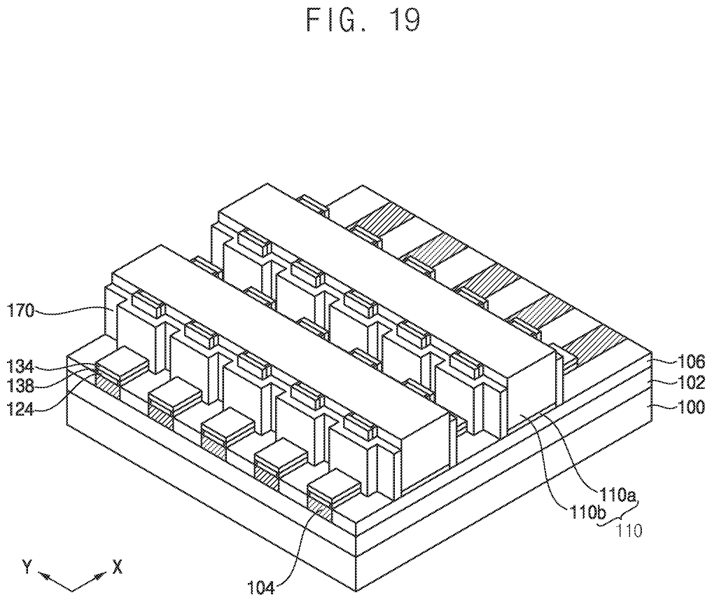

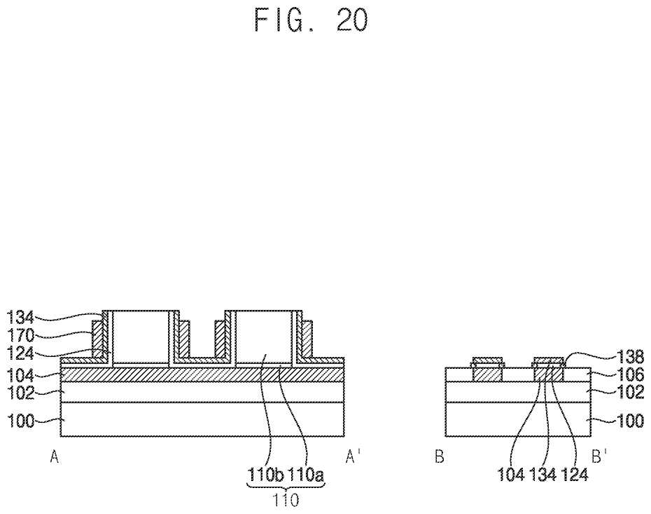

Referring to FIGS. 19 and 20, a second conductive layer may be formed along surfaces of the second lower insulation layer 106, the first metal oxide layer pattern 134, the second metal oxide layer pattern 138 and the mold insulation pattern 110.

The second conductive layer may be anisotropically etched, so that the second conductive layer formed on the upper surface of the mold insulation pattern 110 and the oxide semiconductor layer pattern 124 between the mold insulation patterns 110 may be removed. Thus, the second conductive layer may be separated from each other to form a second conductive layer pattern 170. The second conductive layer pattern 170 may be formed on the sidewall of the mold insulation pattern 110 and on the first and second metal oxide layer patterns 134 and 138 formed on the sidewall of the mold insulation pattern 110. The second conductive layer pattern 170 may extend in the second direction Y. The second conductive layer pattern 170 may serve as a word line.

Two separated second conductive layer patterns 170 facing each other in the first direction X may be disposed on each of the oxide semiconductor layer patterns 124 having the U-shape. The second conductive layer patterns 170 may be disposed on a plurality of oxide semiconductor layer patterns 124 spaced apart from each other in the second direction Y, respectively.

In some example embodiments, the second lower insulation layer 106 and the first and second metal oxide layer patterns 134 and 138 may be exposed between the second conductive layer patterns 170. The oxide semiconductor layer pattern 124 may not be exposed between the second conductive layer patterns 170.

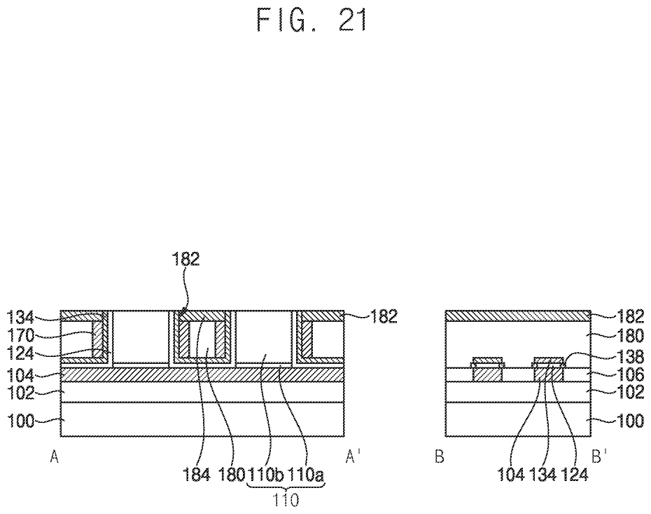

Referring to FIG. 21, a first insulation layer may be formed on the second conductive layer pattern 170, the second lower insulation layer 106, the first metal oxide layer pattern 134, the second metal oxide layer pattern 138 and the mold insulation pattern 110 to completely fill the second trench 152. Thereafter, the first insulation layer may be planarized until the upper surface of the mold insulation pattern 110 may be exposed. An upper portion of the first insulation layer may be additionally etched to form a first insulation layer pattern 180 filling a space between the second conductive layer patterns 170. The upper surfaces of the second conductive layer pattern 170 and the first insulation layer pattern 180 may be lower than the upper surface of the mold insulation pattern 110, so that a first recess 182 may be formed between the mold insulation patterns 110.

A capping layer pattern 184 may be formed in the first recess 182. The capping layer pattern 184 may include an insulation material. In some example embodiments, the capping layer pattern 184 may include silicon nitride, silicon oxynitride, silicon carbide, or the like, however example embodiments are not limited thereto.

According to the above process, upper surfaces of the mold insulation pattern 110, the capping layer pattern 184 and the oxide semiconductor layer pattern 124 may be exposed to the outside.

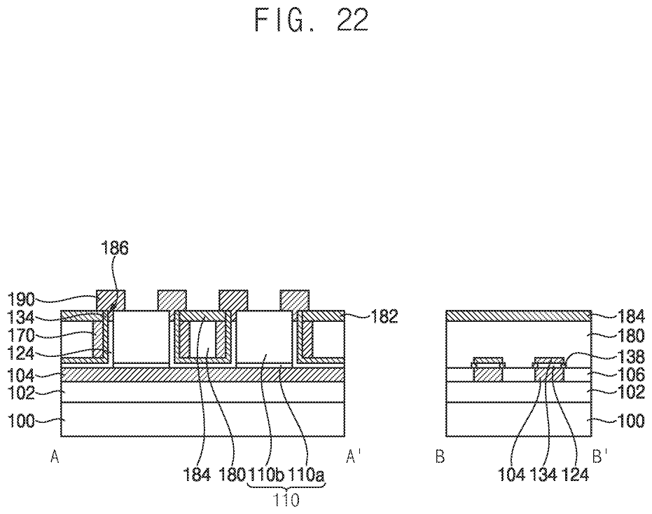

Referring to FIG. 22, an upper portion of the oxide semiconductor layer pattern 124 may be removed to form a second recess 186 on the oxide semiconductor layer pattern 124. As the second recess 186 is formed, the height of the upper surface of the oxide semiconductor layer pattern 124 may be lowered.

A third conductive layer may be formed on the capping layer pattern 184, the mold insulation pattern 110 and the oxide semiconductor layer pattern 124 to fill the second recess 186. The third conductive layer may be patterned to form third conductive layer patterns 190.

Each of the third conductive layer patterns 190 may contact an end (i.e., an uppermost surface) of the oxide semiconductor layer pattern 124. The mold insulation pattern 110 and the capping layer pattern 184 may be exposed between the third conductive layer patterns 190.

The third conductive layer pattern 190 may serve as a pad conductive pattern connected to a capacitor.

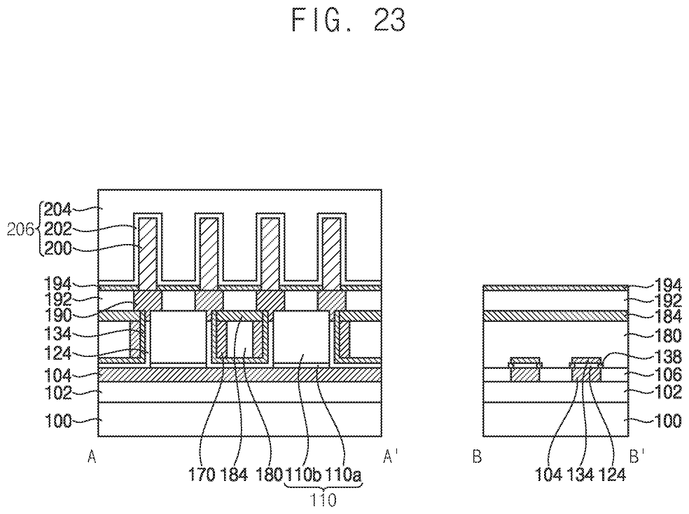

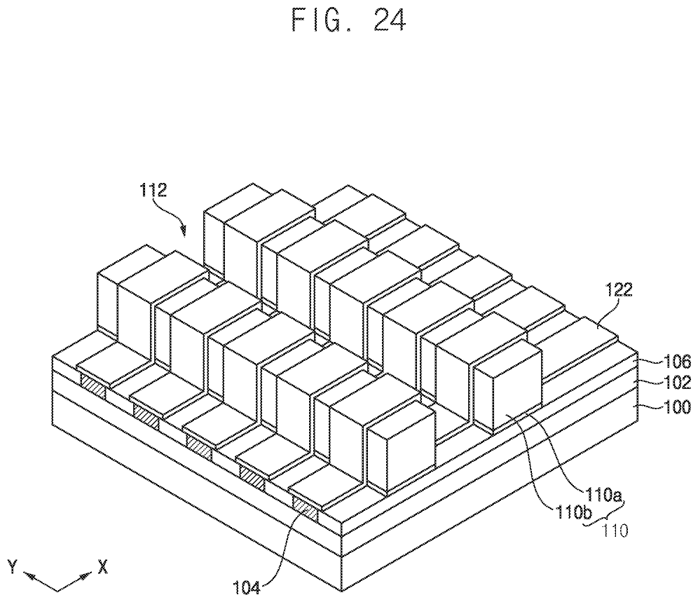

Referring to FIG. 23, an insulation layer may be formed on the third conductive layer pattern 190, the mold insulation pattern 110 and the capping layer pattern 184 to fill a space between the third conductive layer patterns 190. An upper portion of the insulation layer may be planarized until an upper surface of the third conductive layer patterns 190 may be exposed to form a second insulation layer pattern 192. Accordingly, upper surfaces of the third conductive layer patterns 190 and the second insulation layer pattern 192 may be coplanar with each other.

An etch stop layer 194 may be formed on the second insulation layer pattern 192 and the third conductive layer pattern 190. The capacitor 206 may be formed on the third conductive layer pattern 190 through the etch stop layer 194. The capacitor 206 may contact the upper surface of the third conductive layer pattern 190. The capacitor 206 may include a lower electrode 200, a dielectric layer 202, and an upper electrode 204 sequentially stacked. The lower electrode 200 may directly contact the upper surface of the third conductive layer pattern 190. The lower electrode 200 may have a pillar shape or a cylinder shape, however example embodiments are not limited thereto.

As described above, a semiconductor device may be manufactured.

According to the above process, undesired damage and/or removal of the oxide semiconductor layer pattern 124 may be limited and/or prevented during the removal process of the first and second sacrificial layer patterns 144 and 160a. In addition, the first and second metal oxide layer patterns 134 and 138 formed on the oxide semiconductor layer pattern 124 may serve as a gate insulation layer of a vertical channel transistor. Accordingly, the vertical channel transistor may be manufactured by a simple process, and may have excellent characteristics.

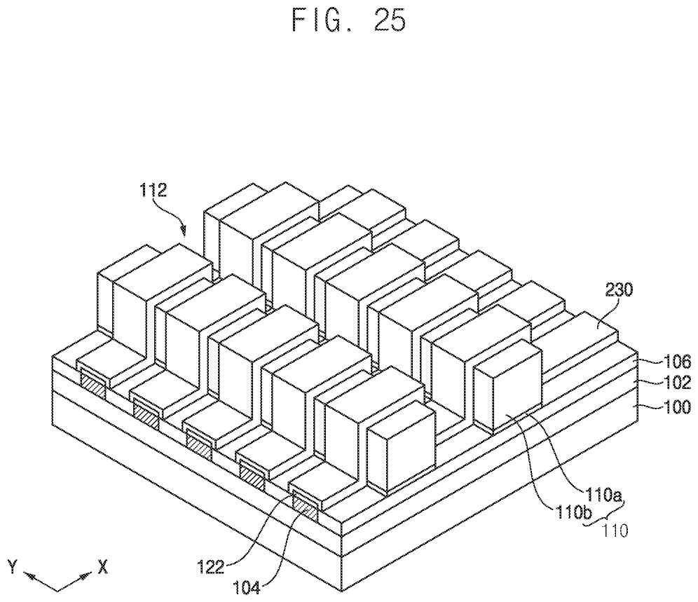

FIGS. 24 to 31 are perspective views and cross-sectional views illustrating a method of manufacturing a semiconductor device in accordance with various example embodiments.

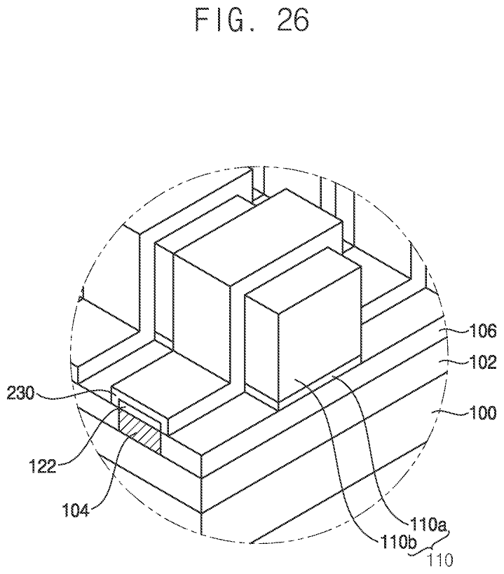

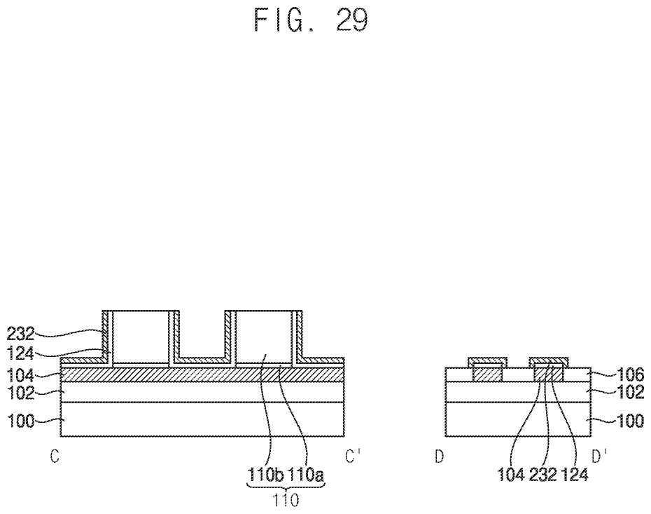

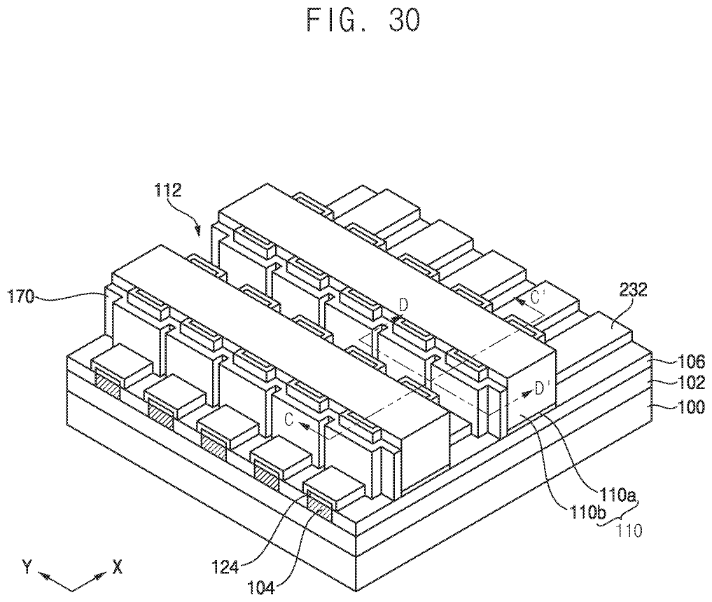

FIGS. 24, 25, 27, 28, 30 and 31 are perspective views, and FIGS. 29 and 31 are cross-sectional views. FIG. 26 is an enlarged perspective view of a portion of a semiconductor device. Each of the cross-sectional views includes cross-sectional views taken along a line of C-C′ and a line of D-D′ in FIG. 28.

Referring to FIG. 24, first, the processes described with reference to FIGS. 5 to 7 may be performed. Therefore, the first lower insulation layer 102, the first conductive layer pattern 104, the second lower insulation layer 106, the mold insulation pattern 110 and the oxide semiconductor layer 120 may be formed on the substrate 100, as shown in FIG. 7.

An etching mask pattern may be formed on the oxide semiconductor layer 120. The etching mask pattern may overlap with an upper surface of the first conductive layer pattern 104.

The oxide semiconductor layer 120 may be etched using the etching mask to form a preliminary oxide semiconductor layer pattern 122. The preliminary oxide semiconductor layer pattern 122 may be conformally formed along the upper surface of the first conductive layer pattern 104 and the surface of the mold insulation pattern 110, and may extend in the first direction X.

The preliminary oxide semiconductor layer pattern 122 may contact the upper surface of the first conductive layer pattern 104. In some example embodiments, the preliminary oxide semiconductor layer pattern 122 may cover the first conductive layer pattern 104.

Thereafter, the etching mask pattern may be removed. Thus, the surface of the preliminary oxide semiconductor layer pattern 122 may be exposed.

Referring to FIGS. 25 and 26, a preliminary metal oxide layer pattern 230 may be selectively formed on the exposed surface of the preliminary oxide semiconductor layer pattern 122.

In some example embodiments, the preliminary metal oxide layer pattern 230 may be formed by reacting with the exposed surface of the preliminary oxide semiconductor layer pattern 122. A sidewall of the preliminary oxide semiconductor layer pattern 122 may be replaced with the preliminary metal oxide layer pattern 230 by a partial thickness.

Thus, the preliminary metal oxide layer pattern 230 may cover an entire surface of the preliminary oxide semiconductor layer pattern 122. In this case, the preliminary metal oxide layer pattern 230 may not substantially cover the surface of the second lower insulation layer 106, and may not substantially be formed on the upper surface of the mold insulation pattern 110.

In some example embodiments, a metal precursor may be introduced onto the preliminary oxide semiconductor layer pattern 122, and the metal precursor may react with an oxide in the preliminary oxide semiconductor layer pattern 122 to form the preliminary metal oxide layer pattern 230. The process of forming the preliminary metal oxide layer pattern 230, may be done without introducing an oxygen agent (e.g., water). When the preliminary metal oxide layer pattern 230 including aluminum oxide is formed, an aluminum precursor, e.g., trimethyl aluminum (TMA), aluminum chloride, or the like may be used. However, example embodiments are not limited thereto. When the preliminary metal oxide layer pattern 230 including a hafnium oxide layer is formed, a hafnium precursor may be used. When the preliminary metal oxide layer pattern 230 including a titanium oxide layer is formed, a titanium precursor may be used. When the preliminary metal oxide layer pattern 230 including a zirconium oxide layer is formed, a zirconium precursor may be used.

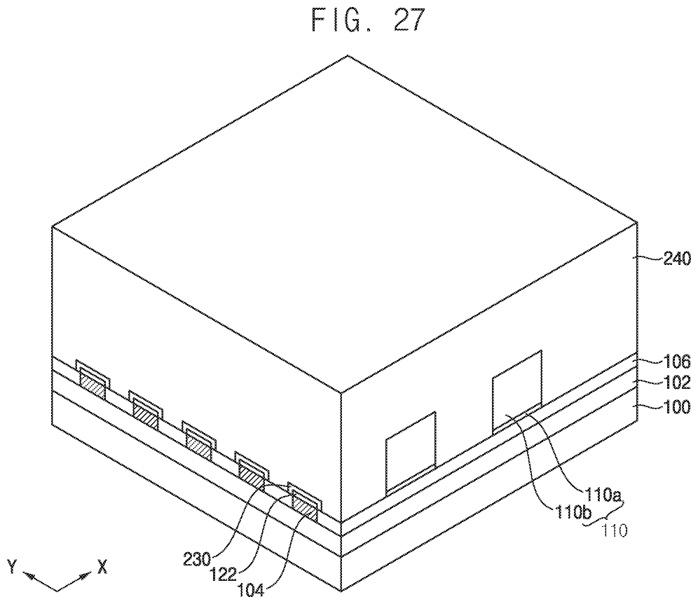

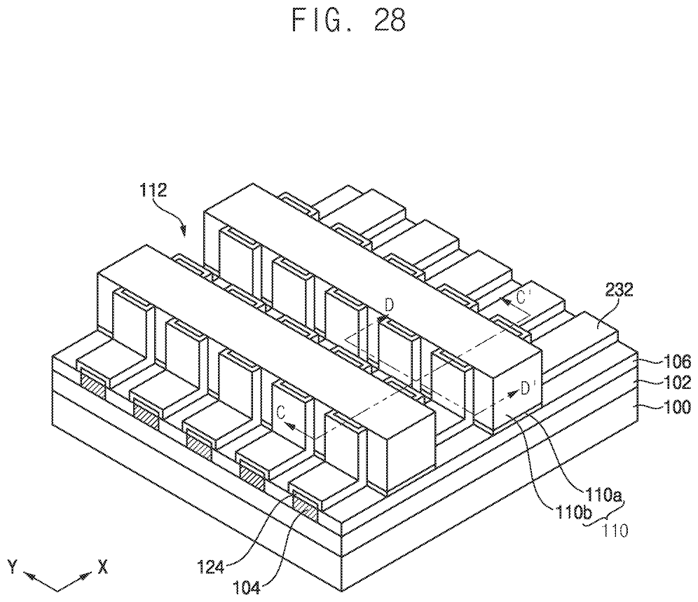

Referring to FIG. 27, a sacrificial layer 240 may be formed on the preliminary metal oxide layer pattern 230, the second lower insulation layer 106 and the mold insulation pattern 110. The sacrificial layer 240 may fill a trench between the mold insulation patterns. Also, an upper surface of the sacrificial layer 240 may be substantially flat, and the upper surface of the sacrificial layer 240 may be higher than an uppermost surface of the preliminary metal oxide layer pattern 230.

In some example embodiments, the sacrificial layer 240 may include a spin-on hard mask material. The spin-on hard mask material may include amorphous carbon.

Since the upper surface and sidewalls of the preliminary oxide semiconductor layer pattern 122 are surrounded by the preliminary metal oxide layer pattern 230, the preliminary oxide semiconductor layer pattern 122 may not directly contact the sacrificial layer 240.

Referring to FIGS. 28 and 29, upper portions of the sacrificial layer 240, the preliminary metal oxide layer pattern 230, and the preliminary oxide semiconductor layer pattern 122 may be removed by a planarization process until the upper surface of the mold insulation pattern 110 may be exposed. Therefore, the sacrificial layer 240, the preliminary metal oxide layer pattern 230, and the preliminary oxide semiconductor layer pattern 122 may be separated to form a sacrificial layer pattern, a metal oxide layer pattern 232 and an oxide semiconductor layer pattern 124. The planarization process may include an etch-back process or a chemical mechanical polishing process.

Thereafter, the sacrificial layer pattern may be removed. The removing process of the sacrificial layer pattern may include an ashing process and a wet cleaning process using a cleaning solution (i.e., a chemical). The wet cleaning process may be performed after the ashing process.

Most of the surface of the oxide semiconductor layer pattern 124 may be covered with the metal oxide layer pattern 232. The surface of the sacrificial layer pattern may not directly contact the oxide semiconductor layer pattern 124. Therefore, the oxide semiconductor layer pattern 124 may not be exposed at a portion where the sacrificial layer pattern is removed. The metal oxide layer pattern 232 may be exposed at the portion where the sacrificial layer pattern is removed. The metal oxide layer pattern 232 may have an etch resistance higher than an etch resistance the oxide semiconductor layer pattern 124 in the ashing process and the wet cleaning process. Therefore, in the removing process of the sacrificial layer pattern, the metal oxide layer pattern 232 may not be removed or damaged. Since the oxide semiconductor layer pattern 124 is protected by the metal oxide layer pattern 232, removal or damage of the oxide semiconductor layer pattern 124 may be limited or prevented. In addition, after the removal process of the sacrificial layer pattern, residues of the sacrificial layer pattern may not remain on a surface of the metal oxide layer pattern 232.

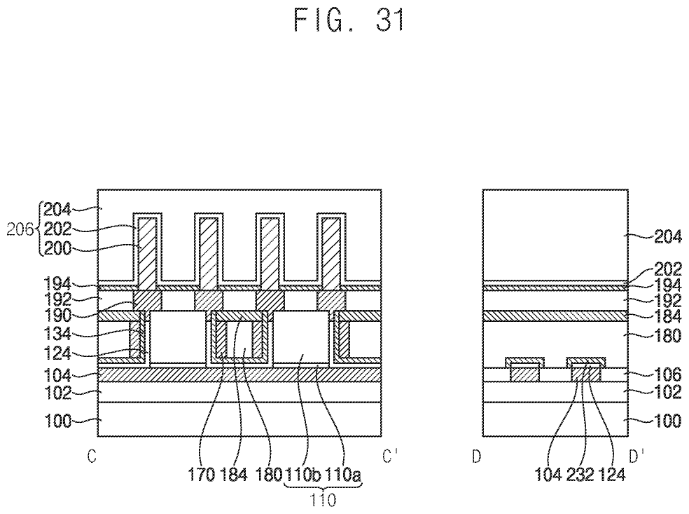

Referring to FIG. 30, a second conductive layer pattern 170 may be formed on the sidewall of the mold insulation pattern 110 and the metal oxide layer pattern 232 formed on the sidewall of the mold insulation pattern 110.

Referring to FIG. 31, processes substantially the same as those described with reference to FIGS. 19 to 23 may be performed to form the first insulation layer pattern 180, the capping layer pattern 184, the third conductive layer pattern 190, the etch stop layer 194, and the capacitor 206.

As shown in FIGS. 30 and 31, the DRAM device may be substantially the same as the DRAM device shown in FIGS. 1 and 2, except that one metal oxide layer pattern 232 may surround the surface of the oxide semiconductor layer pattern 124.

The vertical channel transistor included in the semiconductor device in accordance with various example embodiments may be used as a selection transistor of various memory devices such as a DRAM device, NAND flash device, or the other similar memory devices, however example embodiments are not limited thereto. In addition, the semiconductor device in accordance with various example embodiments may be used as memory devices included in electronic products such as mobile devices, memory cards, and computers, however example embodiments are not limited thereto.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims. Furthermore, example embodiments are not necessarily mutually exclusive with one another. For example, some example embodiments may include one or more features described with reference to one or more figures, and may also include one or more other features described with reference to one or more other figures.

What is claimed is:

1. Method for manufacturing a semiconductor device, comprising:
forming mold insulation patterns on a substrate, each of the mold insulation patterns extending in a second direction parallel to an upper surface of the substrate;
forming an oxide semiconductor layer conformally on sidewalls and upper surfaces of the mold insulation patterns and the substrate between the mold insulation patterns;
forming a first metal oxide layer on the oxide semiconductor layer to cover the oxide semiconductor layer;
forming a first sacrificial layer on the first metal oxide layer to fill a trench between the mold insulation patterns;
patterning the first sacrificial layer, the first metal oxide layer, and the oxide semiconductor layer to form a first structure extending a first direction, parallel to the upper surface of the substrate and perpendicular to the second direction, the first structure including a preliminary first metal oxide layer pattern, a preliminary oxide semiconductor layer pattern and a first sacrificial layer pattern stacked;
forming a preliminary second metal oxide layer pattern selectively on a sidewall of the preliminary oxide semiconductor layer pattern;
removing selective portions of the first structure and the preliminary second metal oxide layer pattern from the upper surfaces of the mold insulation patterns to form an oxide semiconductor layer pattern, a first metal oxide layer pattern, and a second metal oxide layer pattern covering a surface of the oxide semiconductor layer pattern on the sidewalls of the mold insulation patterns and on the substrate between the mold insulation patterns;
removing the remaining first sacrificial layer pattern; and
forming a conductive layer pattern extending in the second direction on the sidewalls of the mold insulation patterns, and on the first and second metal oxide layer patterns formed on the sidewalls of the mold insulation patterns.

2. The method of claim 1, wherein the oxide semiconductor layer pattern includes at least one of InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, or YbxGayZnzO.

3. The method of claim 1, wherein the first and second metal oxide layer patterns include substantially the same material composition.

4. The method of claim 1, wherein the first and second metal oxide layer patterns include at least one of aluminum oxide, zirconium oxide, hafnium oxide, or titanium oxide.

5. The method of claim 1, wherein the oxide semiconductor layer pattern includes InxGayZnzO, and the first and second metal oxide layer patterns includes aluminum oxide.

6. The method of claim 1, wherein the second metal oxide layer pattern is formed by introducing a metal precursor onto the preliminary oxide semiconductor layer pattern and reacting the metal precursor with an oxide included in the preliminary oxide semiconductor layer pattern.

7. The method of claim 1, wherein the first metal oxide layer is formed by introducing a metal precursor onto the preliminary oxide semiconductor layer pattern and reacting the metal precursor with an oxide included the preliminary oxide semiconductor layer pattern, or by alternately introducing metal precursor and an oxygen agent.

8. The method of claim 1, wherein after forming the preliminary second metal oxide layer pattern, forming a second sacrificial layer on the substrate to cover the first structure and the preliminary second metal oxide layer pattern,
wherein the second sacrificial layer includes a material substantially the same material composition as a material of the first sacrificial layer pattern, and
wherein the first sacrificial layer pattern and the second sacrificial layer are removed together in one or more removal processes.

9. The method of claim 1, wherein the first sacrificial layer pattern includes a spin-on hard mask material.

10. The method of claim 1, wherein the first sacrificial layer pattern is removed by an ashing process and a cleaning process using a cleaning solution.

11. The method of claim 1, further comprising:
forming a lower conductive layer pattern extending in the first direction on the substrate;
forming a pad conductive pattern connected to an uppermost surface of the oxide semiconductor layer pattern; and
forming a capacitor on the pad conductive pattern.

12. Method for manufacturing a semiconductor device, comprising:
forming first conductive layer patterns on a substrate, each of the first conductive layer patterns extending in a first direction parallel to an upper surface of the substrate;
forming mold insulation patterns on the first conductive layer pattern, each of the mold insulation patterns extending in a second direction parallel to the upper surface of the substrate and perpendicular to the first direction;
forming an oxide semiconductor layer conformally on sidewalls and upper surfaces of the mold insulation patterns and an upper surface of the first conductive layer pattern between the mold insulation patterns;
forming a first metal oxide layer on the oxide semiconductor layer to cover the oxide semiconductor layer;
forming a first sacrificial layer on the first metal oxide layer to fill a trench between the mold insulation patterns;
patterning the first sacrificial layer, the first metal oxide layer and the oxide semiconductor layer to form a first structure extending the first direction, the first structure including a preliminary first metal oxide layer pattern, a preliminary oxide semiconductor layer pattern and a first sacrificial layer pattern stacked;
forming a preliminary second metal oxide layer pattern selectively on a sidewall of the preliminary oxide semiconductor layer pattern;
forming a second sacrificial layer on the substrate to cover the first structure and the preliminary second metal oxide layer pattern;
planarizing upper portions of the first structure, the second sacrificial layer and the preliminary second metal oxide layer pattern to expose the upper surface of the mold insulation pattern to form an oxide semiconductor layer pattern having a U-shaped cross-section, a first metal oxide layer pattern, a second metal oxide layer pattern covering surfaces of the oxide semiconductor layer pattern, and a sacrificial layer structure on the first and second metal oxide layer patterns;
removing the sacrificial layer structure; and
forming a second conductive layer pattern extending in the second direction on the sidewalls of the mold insulation patterns and on the first and second metal oxide layer patterns formed on the sidewalls of the mold insulation patterns.

13. The method of claim 12, wherein the first and second sacrificial layers include a spin-on hard mask material.

14. The method of claim 12, wherein the sacrificial layer structure is removed by an ashing process and a cleaning process using a cleaning solution.

15. The method of claim 12, wherein the second metal oxide layer pattern is formed by introducing a metal precursor onto the preliminary oxide semiconductor layer pattern and reacting the metal precursor with an oxide included in the preliminary oxide semiconductor layer pattern.

16. The method of claim 12, further comprising:
forming a pad conductive pattern connected to an uppermost surface of the oxide semiconductor layer pattern; and
forming a capacitor on the pad conductive pattern.

17. Method for manufacturing a semiconductor device, comprising:
forming a preliminary oxide semiconductor layer pattern on a substrate;
forming a preliminary metal oxide layer pattern selectively on an exposed surface of the preliminary oxide semiconductor layer pattern, the preliminary metal oxide layer pattern covering the exposed surface of the preliminary oxide semiconductor layer pattern;
forming a sacrificial layer on the preliminary metal oxide layer pattern;
removing at least portions of the sacrificial layer, the preliminary metal oxide layer pattern and the preliminary oxide semiconductor layer pattern to form an oxide semiconductor layer pattern, a metal oxide layer pattern, and a sacrificial layer pattern;
removing the remaining sacrificial layer pattern; and
forming a conductive layer pattern on the metal oxide layer pattern.

18. The method of claim 17, wherein the preliminary metal oxide layer pattern is formed by introducing a metal precursor onto the preliminary oxide semiconductor layer pattern and reacting the metal precursor with an oxide included in the preliminary oxide semiconductor layer pattern.

19. The method of claim 17, further comprising forming mold insulation patterns on the substrate, and
wherein the preliminary oxide pattern is conformally formed on sidewalls of the mold insulation patterns and the substrate between the mold insulation patterns.

20. The method of claim 19, wherein the sacrificial layer is removed by an ashing process and a cleaning process using a cleaning solution.
